(19) United States
(12) Patent Application Publication
(10) Pub. No.: US 2024/0006392 A1
(43) Pub. Date: Jan. 4, 2024

(54) INTEGRATED CIRCUIT WITH INDUCTOR IN MAGNETIC PACKAGE

(71) Applicant: TEXAS INSTRUMENTS INCORPORATED, Dallas, TX (US)

(72) Inventors: Anton Winkler, KIRCHDORF AN DER AMPER (DE); Christopher Manack, FLOWER MOUND, TX (US); Jeffrey Morroni, PARKER, TX (US); Hidetoshi Inoue, TOCHIGI-KEN (JP); Yuki Sato, TAKATSU (JP); Kenji Otake, TOKYO (JP)

(21) Appl. No.: 17/852,925

(22) Filed: Jun. 29, 2022

(51) Int. Cl. H01L 25/16; H01L 23/00; H01L 23/31; H01L 23/29; H01L 49/02; H01L 21/54; H01F 27/29; H01F 27/32

(52) U.S. Cl. CPC H01L 25/165; H01L 24/16; H01L 24/32; H01L 24/73; H01L 23/3128; H01L 23/295; H01L 28/10; H01L 28/40; H01L 24/29; H01L 24/81; H01L 24/94; H01L 21/54; H01F 27/292; H01F 27/327; H01L 2224/16227; H01L 2224/32225; H01L 2224/73204; H01L 2224/2919; H01L 2224/29186; H01L 2224/81447; H01F 41/005

(57) ABSTRACT

In one example, an integrated circuit comprises: a substrate; a semiconductor die; metal interconnects coupled between the semiconductor die and the substrate; an insulation layer coupled between the semiconductor die and the substrate, the insulation layer surrounding the metal interconnects; an inductor coupled to the substrate; and a magnetic material encapsulating the semiconductor die, the inductor, the metal interconnects and the insulation layer, the magnetic material having a different material from the insulation layer.

### BACKGROUND

An inductor can store energy in a magnetic field when electric current flows through it, and can provide an electric current by discharging the stored energy. Inductor can have many applications, such as proximity sensing, energy storage, actuation, power transmission, and filtering. The inductor may be coupled to or can be part of an integrated circuit, which can include circuitries that operate with the inductor to support those applications. In some examples, the inductor and the circuitries can be enclosed in an integrated circuit package, which can reduce the footprint of the integrated circuit and shorten the interconnects between the inductor and the circuitries.

### SUMMARY

An integrated circuit comprises: a substrate, a semiconductor die, metal interconnects, an insulation layer, an inductor, and a magnetic material. The metal interconnects are coupled between the semiconductor die and the substrate. The insulation layer is coupled between the semiconductor die and the substrate and surrounds the metal interconnects. The inductor is couple to the substrate. The magnetic material encapsulates the semiconductor die, the inductor, the metal interconnects, and the insulation layer, and have a different material from the insulation layer.

A method comprises: forming an insulation layer on a wafer, patterning the insulation layer, and forming first metal interconnects in the patterned insulation layer. The method further comprises dicing the wafer to form a semiconductor die, the diced wafer also including the first metal interconnects and the patterned insulation layer. The method further comprises: mounting the semiconductor die to a substrate, mounting an inductor to the substrate, and depositing a magnetic material on the semiconductor die and the inductor to form an encapsulation package. The method further comprises forming second metal interconnects outside of the encapsulation package, in which the second metal interconnects are coupled to the first metal interconnects and the inductor.

### BRIEF DESCRIPTION OF THE DRAWINGS

FIGS. 1A and 1B are schematic diagrams of an example integrated circuit.

FIG. 2A, FIG. 2B, FIGS. 3A-3C, and FIGS. 4A-4C are schematic diagrams of examples of an integrated circuit.

FIG. 5 is a flowchart of an example method of fabricating an integrated circuit.

FIGS. 6A through 6V are schematic diagrams that illustrate various operations of the example method of FIG. 5.

### DETAILED DESCRIPTION

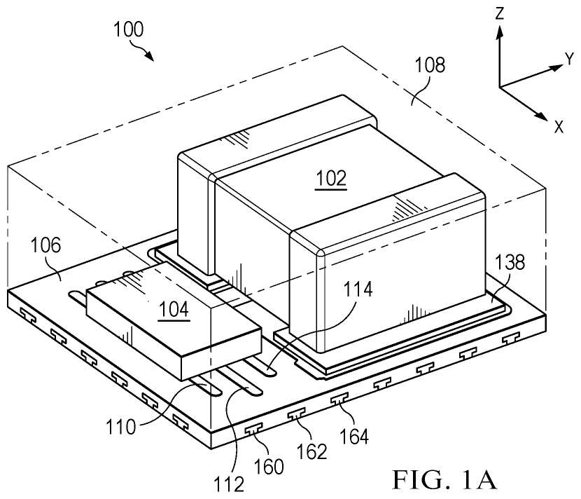

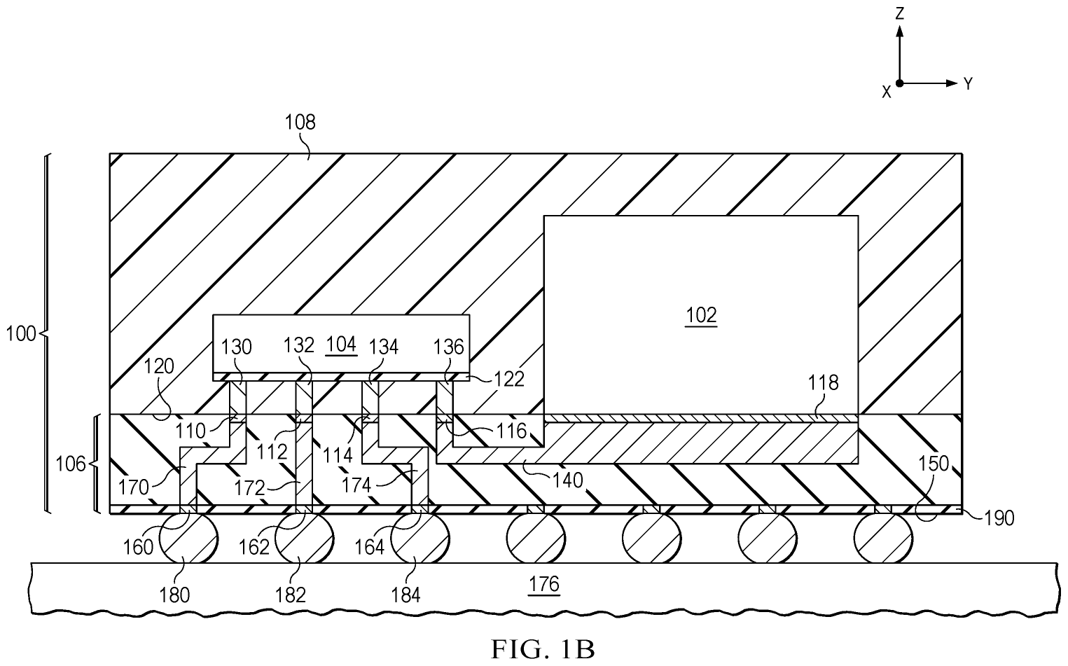

FIG. 1A and FIG. 1B are schematic diagrams that illustrate an example integrated circuit 100. FIG. 1A and FIG. 1B illustrate, respectively, a perspective view and a side view of integrated circuit 100. Referring to FIG. 1A and FIG. 1B, integrated circuit 100 can include an inductor 102 and a semiconductor die 104 mounted to a package substrate 106 and encapsulated in an encapsulation package 108. Inductor 102 can include metal coils surrounding a core. Examples of an inductor core can include an air core, a ferrite core, or an iron powder core. The inductor 102 can also be a molded inductor, in which the coils and the core can be encapsulated in a package made of a molding compound, such as a magnetic molding compound (MMC) having metallic particles (e.g., iron particles) and an insulation material (e.g., a polymer resin) in which the metallic particles are suspended. Encapsulation package 108 can shield the coils and the core and increase the magnetic field density, which can improve the efficiency of inductor 102 in converting between electrical and magnetic energies. Also, encapsulation package 108 can include a molding compound, such as an epoxy molding compound (EMC), that can electrically insulate inductor 102 and semiconductor die 104 from external electrical signals, such as noise signals and electrostatic signals.

Semiconductor die 104 and inductor 102 can form a system to support a particular application, such as proximity sensing, energy storage, actuation, power transmission, and filtering. For example, integrated circuit 100 can include a proximity sensor, in which semiconductor die 104 can include an oscillator and a sensing circuit. The oscillator can drive inductor 102 with an oscillating current signal, and the sensing circuit can sense the frequency of the current signal. A metal object approaching inductor 102 can change the inductance of inductor 102, which can change the frequency of the current signal. The sensing circuit can detect the metal object by detecting the frequency change. As another example, integrated circuit 100 can include a switch-mode power converter to transmit power from a power source to a load. In such example, inductor 102 can provide energy storage, and semiconductor die 104 can include switches to charge and discharge the inductor 102 to set the voltage across the load.

Also, package substrate 106 can provide mechanical support to inductor 102 and semiconductor die 104, and provide electrical connections between the inductor and the semiconductor die, and electrical connections to between integrated circuit 100 and an external device. For example, package substrate 106 can include an electrical insulation material, such as a polymer, an Ajinomoto Build-up Film (ABF), or a ceramic material. Package substrate 106 can also include metal pads 110, 112, 114, 116, and 118, which can be Copper pads, on a surface 120 to which inductor 102 and semiconductor die 104 are mounted.

Also, semiconductor die 104 can include a passivation layer 122, which can be coupled to metal pads 110, 112, 114, and 116 via respective metal interconnects 130, 132, 134, and 136. Each pad can be coupled to a respective metal interconnect via a solder layer. Passivation layer 122 can insulate circuitries in semiconductor die 104 from metal interconnects 130, 132, 134, and 136. Metal interconnects 130 through 136 can include, for example, Copper pillars, solder bumps, and under bump metallization (UBM) interconnects. Also, inductor 102 can be coupled to metal pad 118 via a solder layer. Package substrate 106 can include metal interconnects on or under surface 120 to provide electrical connections between inductor 102 and semiconductor die 104, such as metal interconnect 140 between metal pads 116 and 118.

Package substrate 106 can also include metal pads on a surface 150 opposite to surface 120, such as metal pads 160, 162, and 164 which can include Copper pads or pads made of other metals (e.g., Silver or Palladium). Package substrate 106 can also include metal interconnects, such as Copper interconnects, to provide electrical connections between pads on the opposite surfaces. For example, package substrate 106 can include metal interconnect 170 between metal pads 110 and 160, metal interconnect 172 between metal pads 112 and 162, and metal interconnect 174 between metal pads 114 and 164. The metal pads on surface 150 and the interconnects can provide electrical connections between an external device and integrated circuit 100. For example, metal pads 160, 162, and 164 can be coupled to a printed circuit board (PCB) 176 via respective solder balls 180, 182, and 184, which can provide electrical connections between integrated circuit 100 and an external device (e.g., a power source) on PCB 176. Package substrate 106 can also include a solder resist layer 190 on surface 150 to shield metal interconnects in the package substrate (e.g., metal interconnects 170, 172, and 174) from the solder balls.

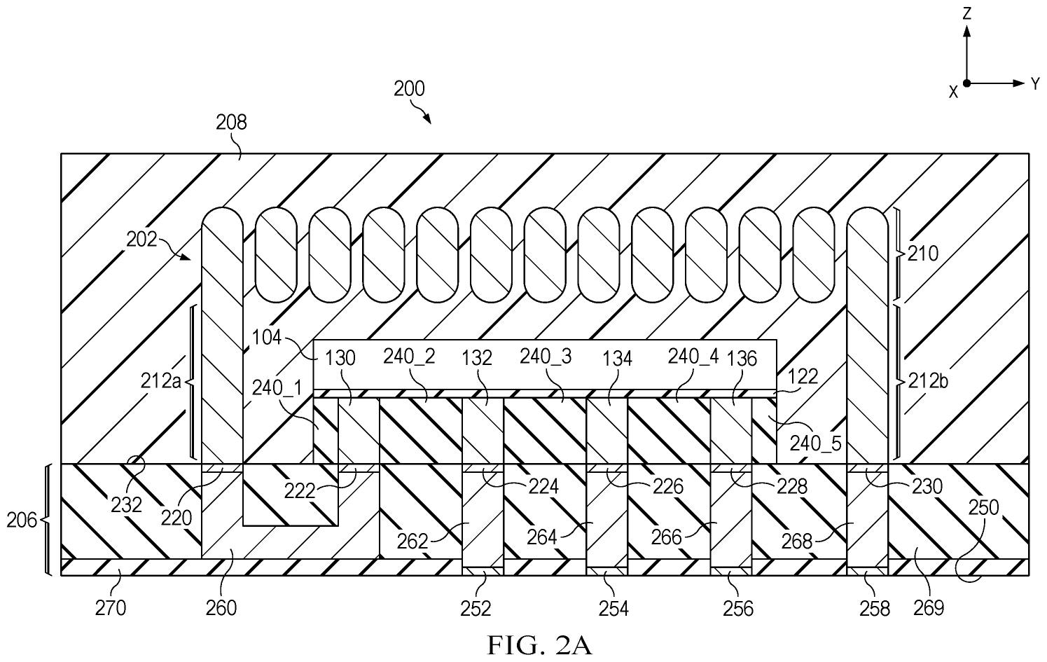

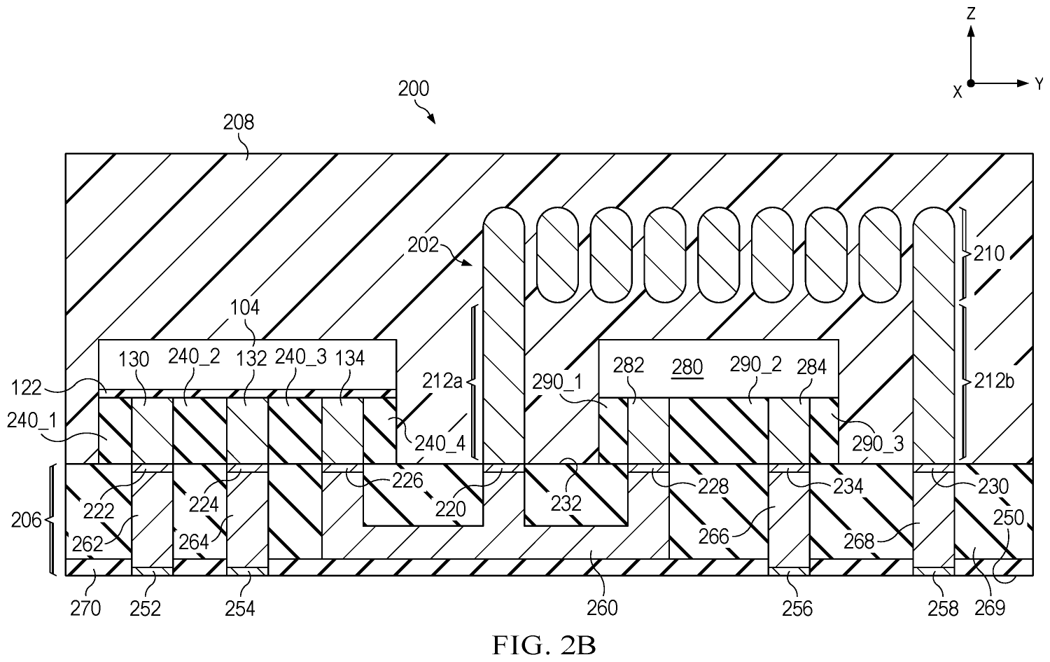

FIG. 2A illustrates an example of integrated circuit 200 that can have a reduced footprint compared with integrated circuit 100 of FIGS. 1A and 1B. FIG. 2A illustrates a side view of integrated circuit 200. Referring to FIG. 2A, integrated circuit 200 can include an inductor 202 and semiconductor die 104 mounted to package substrate 206. Integrated circuit 200 can also include a magnetic material (e.g., MMC) on package substrate 206. The magnetic material can encapsulate inductor 202 and semiconductor die 104 as an encapsulation package 208. Inductor 202 can include a coil portion 210, which can include various types of cores such as a ferrite core and an iron powder core, and stilt portions 212a and 212b that supports coil portion 210 over package substrate 206. Also, semiconductor die 104 can be positioned between stilt portions 212a and 212b and underneath coil portion 210, so that coil portion 210 and semiconductor die 104 can form a device stack. In some examples, coil portion 210 can have openings facing sideways (e.g., along the x/y axes), as shown in FIGS. 3A-3C. In some examples, coil portion 210 can have openings facing up/down over semiconductor die 104 (e.g., along the z-axis), as shown in FIGS. 4A-4C.

Package substrate 206 can include metal pads 220, 222, 224, 226, 228, and 230, which can be Copper pads, on a surface 232 on which inductor 202 and semiconductor die 104 are attached. Integrated circuit 200 can include metal interconnects 130, 132, 134, and 136 coupled between semiconductor die 104 and respective metal pads 222, 224, 226, and 228 via a solder layer. Also, stilt portions 212a and 212b of inductor 202 can be coupled to respective metal pads 220 and 230 via a solder layer.

Integrated circuit 200 can include an insulation layer 240 between passivation layer 122 of semiconductor die 104 and surface 232 of package substrate 206. Insulation layer 240 can surround the metal interconnects coupled between semiconductor die 104 and package substrate 206 and can include sublayers sandwiched between adjacent metal interconnects of semiconductor die 104, and between metal interconnects and stilts of inductor 202, to provide electrical insulation among the metal interconnects of semiconductor die 104 and inductor 202. For example, insulation sublayer 240_1 can provide electrical insulation between stilt portion 212a and metal interconnect 130, insulation sublayer 240_2 can provide electrical insulation between metal interconnects 130 and 132, insulation layer 240_3 can provide electrical insulation between metal interconnects 132 and 134, insulation layer 240_4 can provide electrical insulation between metal interconnects 134 and 136, and insulation layer 240_5 can provide electrical insulation between metal interconnect 136 and stilt portion 212b. In some examples, insulation layer 240 can include a dielectric material with a high break down voltage, such as a polymer material (e.g., Polyimide (PI), Polybenzoxazole (PBO)), or an oxide material (e.g., Silicon Dioxide). Both insulation layer 240 and metal interconnects 130 through 136 are encapsulated in encapsulation package 208.

Package substrate 206 can also include metal pads on a surface 250 opposite to surface 232, such as metal pads 252, 254, 256, and 258 which can include Copper pads or pads made of other metals (e.g., Silver and Palladium). Metal pads 252, 254, 256, and 258 can be coupled to an external device via solder balls, such as PCB 176 and solder balls 180 through 184 of FIG. 1, to provide electrical connections between integrated circuit 200 and the external device. Package substrate 206 can also include metal interconnects, such as Copper interconnects, that connect between the metal pads of the same or different surfaces. For example, package substrate 206 can include a metal interconnect 260 coupled between metal pads 220 and 222 (on surface 232) to provide an electrical connection between inductor 202 and semiconductor die 104. Package substrate 206 can also include a metal interconnect 262 coupled between metal pads 224 and 252, a metal interconnect 264 coupled between metal pads 226 and 254, a metal interconnect 266 coupled between metal pads 228 and 256, and a metal interconnect 268 coupled between metal pads 230 and 258, to provide electrical connections between the external device and inductor 202 and/or semiconductor die 104. Package substrate 206 can include an electrical insulation layer 269, such as a polymer, ABF, or a ceramic material, to provide electrical insulation among the metal interconnects and the metal pads. Also, package substrate 206 can include a solder resist layer 270 below surface 250 to shield metal interconnects in the package substrate (e.g., metal interconnects 260, 262, 264, 266, and 268) from the solder balls and the external device.

Also, as described above, inductor 202 and semiconductor die 104 can be encapsulated in encapsulation package 208 on package substrate 206, and encapsulation package 208 can include a magnetic material such as MMC. The MMC can have metallic particles (e.g., iron particles) and an insulation material (e.g., a polymer resin) in which the metallic particles are suspended. Encapsulation package 208 can shield inductor 202 and increase the magnetic field density, which can improve the efficiency of inductor 202 in converting between electrical and magnetic energies. The MMC material of encapsulation package 208 can fill the space within inductor 202, such as in the center of coil portion 210 (e.g., if inductor 202 has an air core) and between individual coils of coil portion 210. The MMC material can also fill the space between coil portion 210 and semiconductor die 104, except in the space filled by insulation layer 240, and encapsulate insulation layer 240 and metal interconnects 130 through 136. Insulation layer 240 can have a higher breakdown voltage than the MMC material.

FIG. 2B illustrates another example of integrated circuit 200. Referring to FIG. 2B, semiconductor die 104 can be positioned outside of and adjacent to inductor 202. Integrated circuit 200 can include another circuit component, such as a capacitor 280, positioned under coil portion 210 and stilt portions 212a and 212b, so that coil portion 210 and capacitor 280 can form a device stack. In some examples, semiconductor die 104 and capacitor 280 can positioned under coil portion 210 and stilt portions 212a and 212b to form the device stack.

Package substrate 206 can include metal pad 234 (e.g., Copper pad) in addition to metal pads 220 through 230 on surface 232 on which semiconductor die 104 and capacitor 280 are attached. Integrated circuit 200 can also include metal interconnects 130, 132, and 136 (e.g., Copper pillars, solder bumps, or UBM interconnects) coupled between semiconductor die 104 and respective metal pads 222, 224, and 226 of package substrate 206. Integrated circuit 200 can also include metal interconnects 282 and 284 (e.g., Copper pillars, solder bumps, or UBM interconnects) coupled between capacitor 280 and respective metal pads 228 and 234. Package substrate 206 can also include metal interconnects coupled between metal pads on surface 232 and on surface 250 to provide external access to semiconductor die 104, inductor 202, and capacitor 280. For example, package substrate 206 can include metal interconnect 262 coupled between metal pads 222 and 252, metal interconnect 264 coupled between metal pads 224 and 254, metal interconnect 266 coupled between metal pads 234 and 256, and metal interconnect 268 coupled between metal pads 230 and 258. Package substrate 206 can also include metal interconnect 260 coupled among metal pads 220, 226, and 228 to provide an internal electrical connection among semiconductor die 104, inductor 202, and capacitor 280.

Also, integrated circuit 200 can include insulation layer 240 between passivation layer 122 of semiconductor die 104 and surface 232 of package substrate 206, and insulation layer 290 between capacitor 280 and surface 232 of package substrate 206. Insulation layers 240 and 290 can surround the metal interconnects of respective semiconductor die 104 and capacitor 280, and can include sublayers sandwiched between adjacent metal interconnects to provide electrical insulation. For example, insulation sublayer 240_1 can provide electrical insulation between metal interconnect 130 and outside of encapsulation package 208, insulation sublayer 240_2 can provide electrical insulation between metal interconnects 130 and 132, insulation layer 240_3 can provide electrical insulation between metal interconnects 132 and 134, and insulation layer 240_4 can provide electrical insulation between metal interconnect 134 and stilt portion 212a. Also, insulation sublayer 290_1 can provide electrical insulation between stilt portion 212a and metal interconnect 282, insulation sublayer 290_2 can provide electrical insulation between metal interconnects 282 and 284, and insulation sublayer 290_3 can provide electrical insulation between metal interconnect 290_3 and stilt portion 212b. Both insulation layers 240 and 290 can include a dielectric material with a higher break down voltage than the MMC material of encapsulation package 208, such as PI, PBO, or Silicon Dioxide.

By placing semiconductor die 104 and/or capacitor 280 below coil portion 210 of inductor 202, integrated circuit 200 of FIG. 2A and FIG. 2B can have a reduced footprint (e.g., on the x-y plane), which can also shorten the metal interconnects between semiconductor die 104 and inductor 202 (e.g., metal interconnect 260) and reduce their parasitic capacitances. The arrangements of FIG. 2A and FIG. 2B also allow the coil portion of the inductor to cover most of the footprint of integrated circuit 200, and a larger inductor with increased inductance can be included in integrated circuit 200. Also, by encapsulating inductor 202 in an MMC encapsulation package, the magnetic field density within integrated circuit 200 can be increased, which can improve the efficiency of inductor 202 in converting between electrical and magnetic energies. Further, the metal interconnects (e.g., Copper pillars and/or UBM) of semiconductor die 104 can be encapsulated (and insulated) with insulation layer 240 made of a material having a higher breakdown voltage than MMC, such as PI and PBO, which can reduce the risk of electrical shorts between adjacent interconnects, and between inductor 202 and the interconnects, which can improve safety and reliability while coil portion 210 can be encapsulated in MMC to improve magnetic field density. All these can improve the performance of integrated circuit 200.

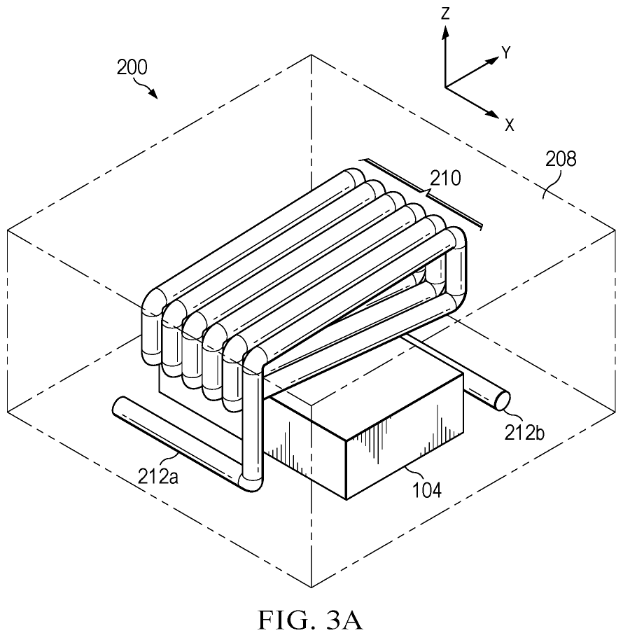

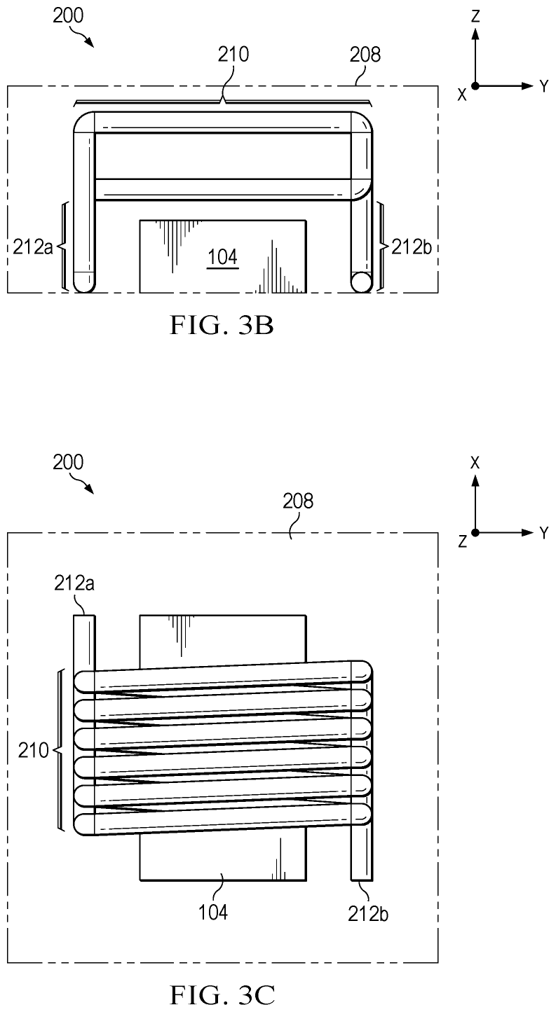

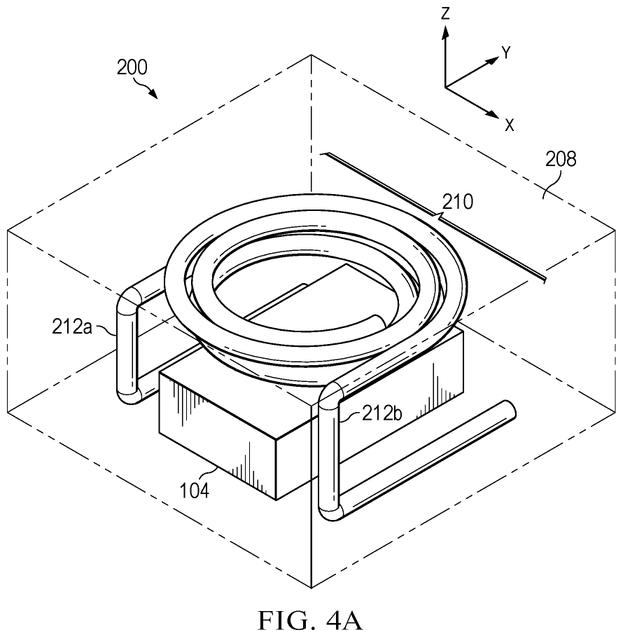

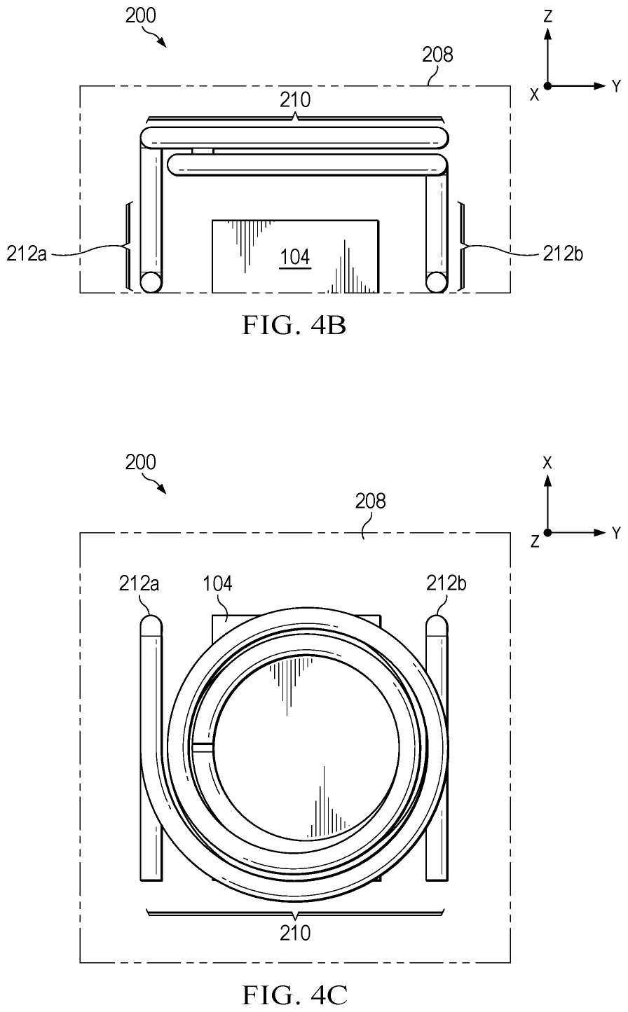

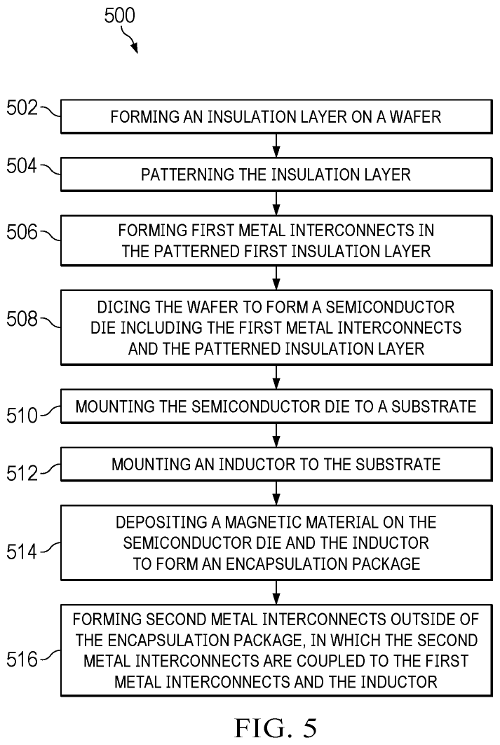

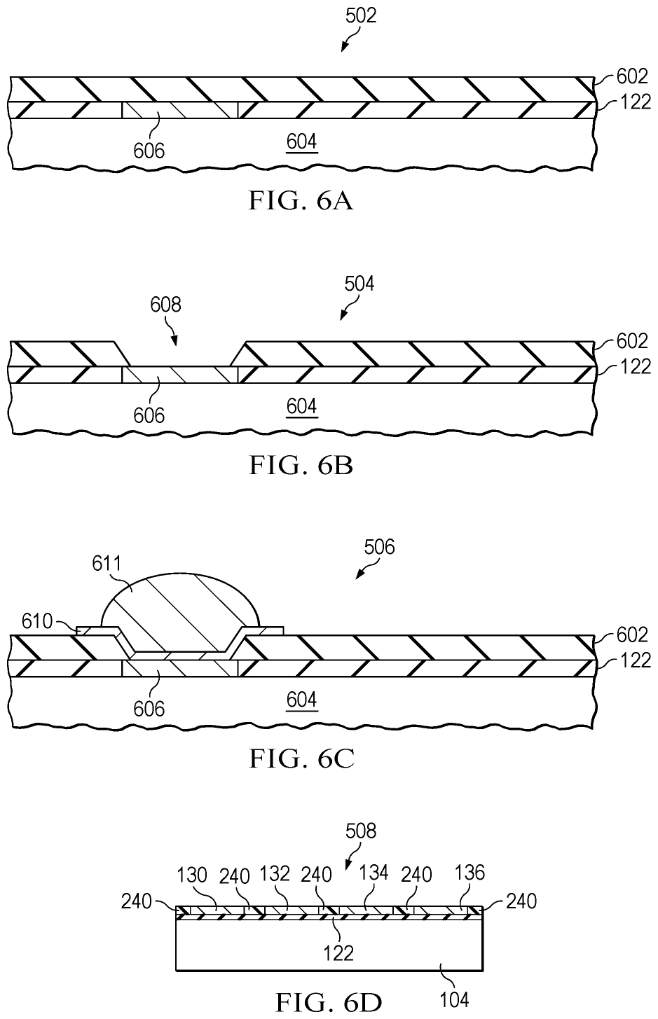

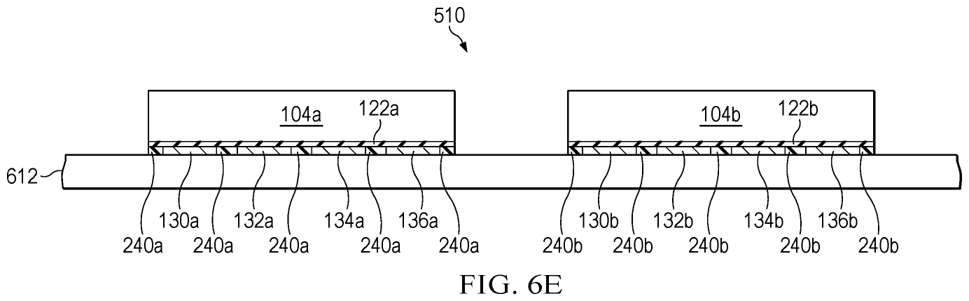

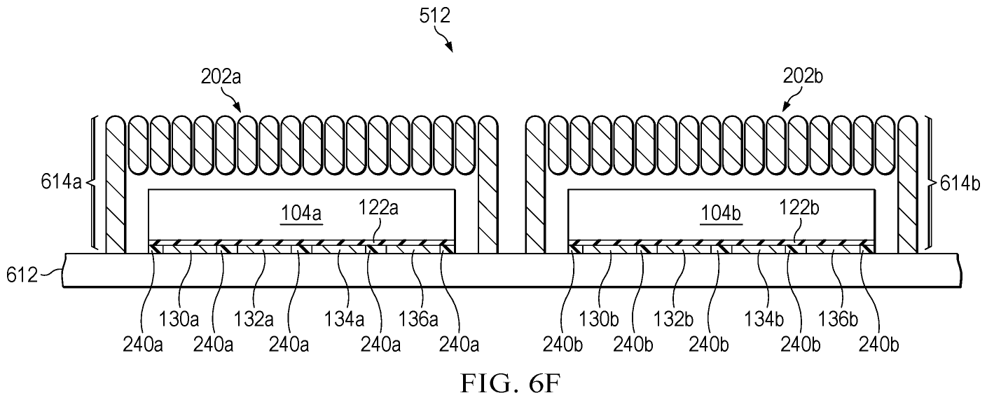

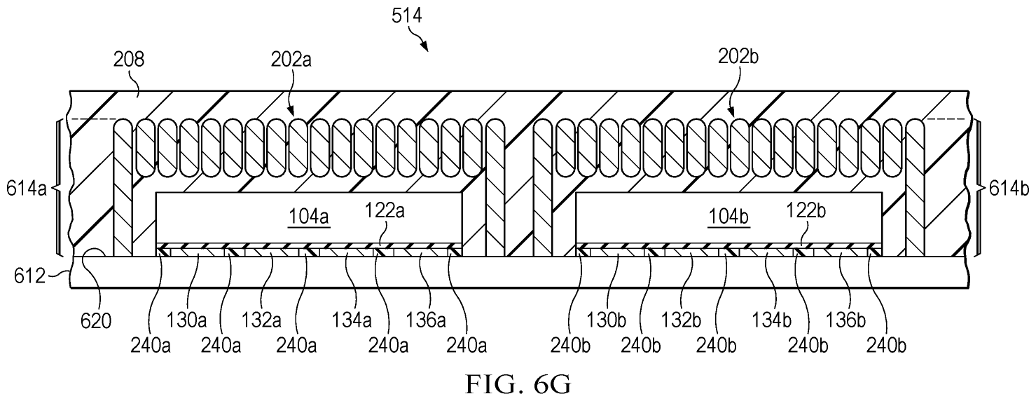

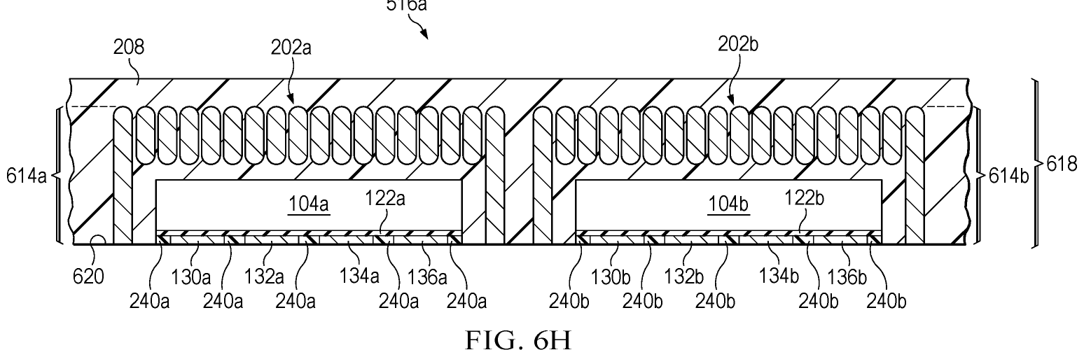

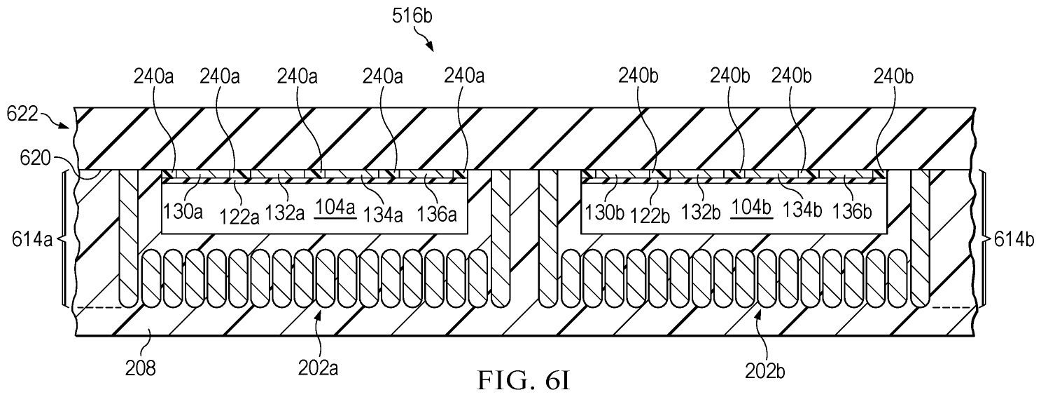

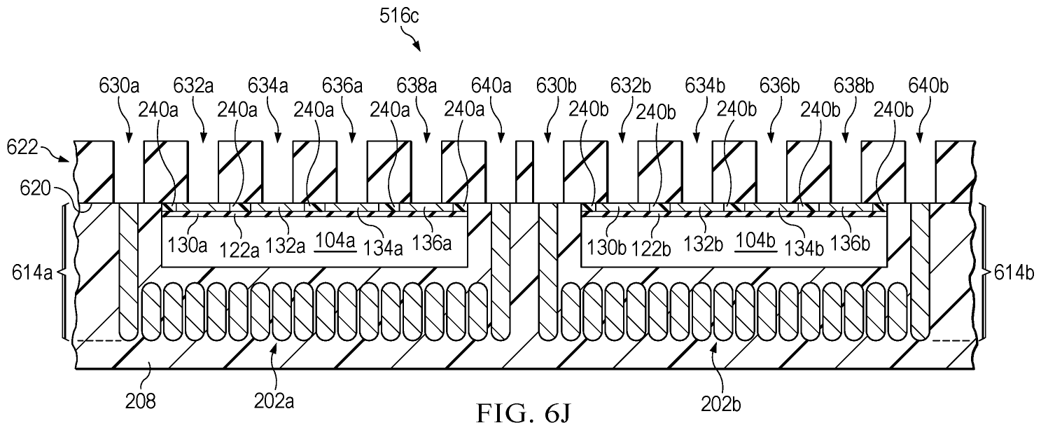

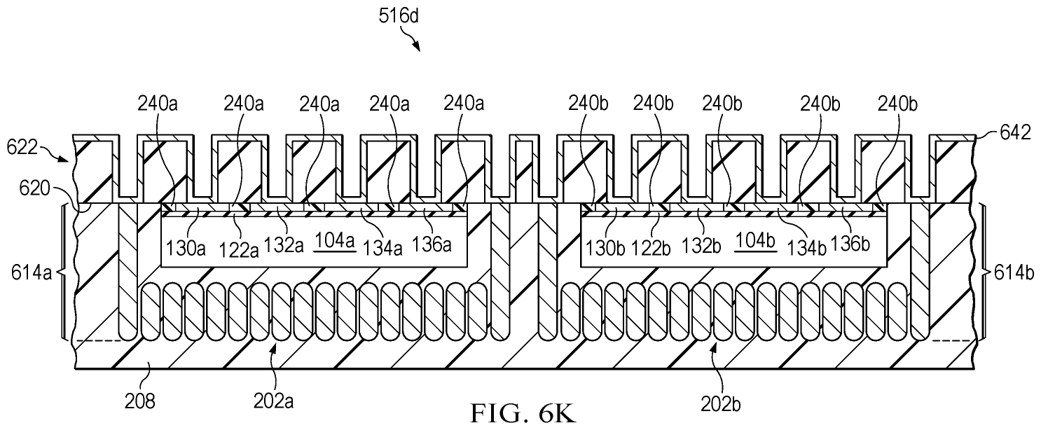

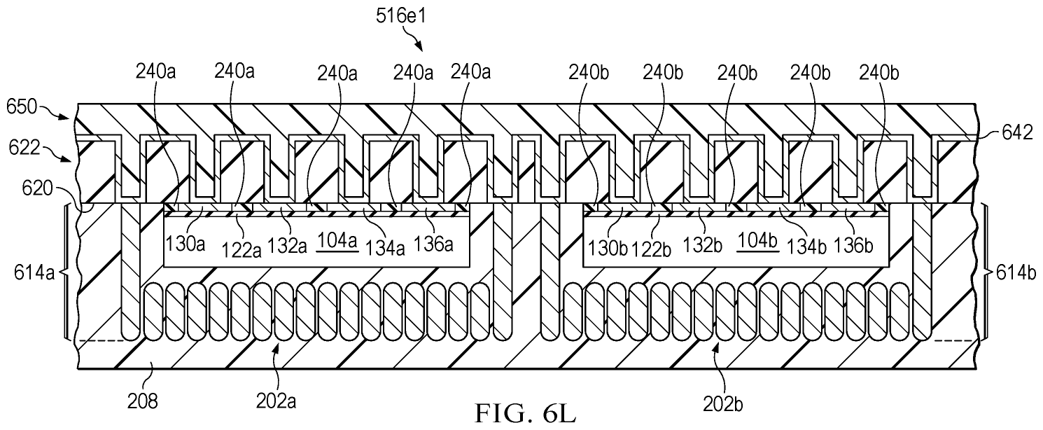

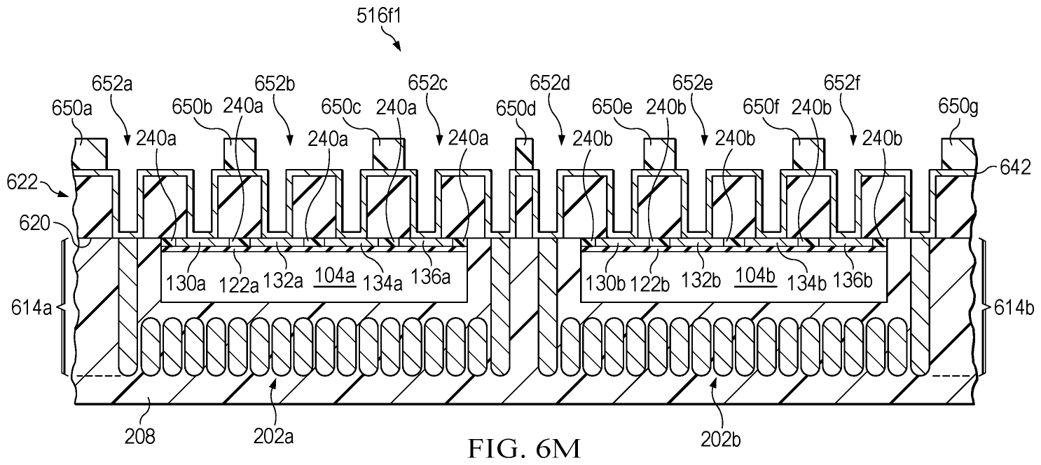

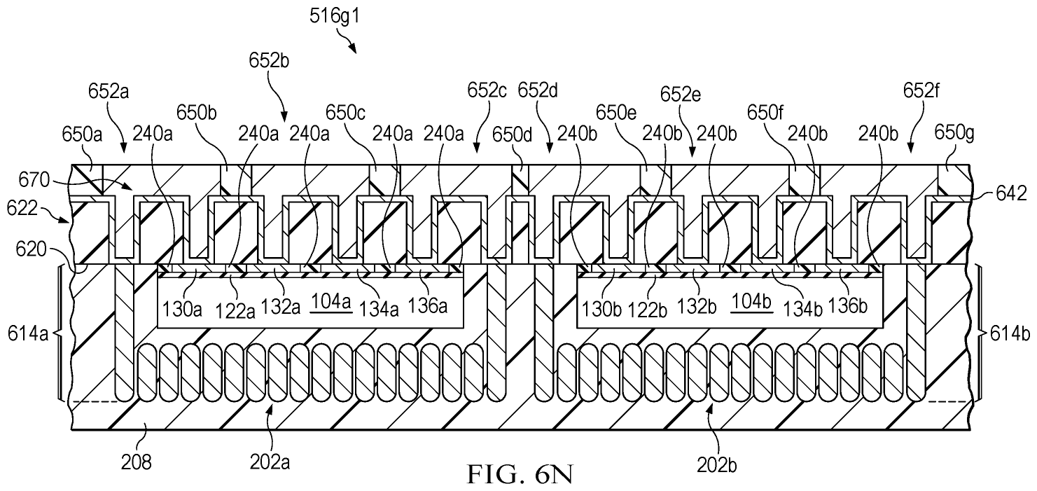

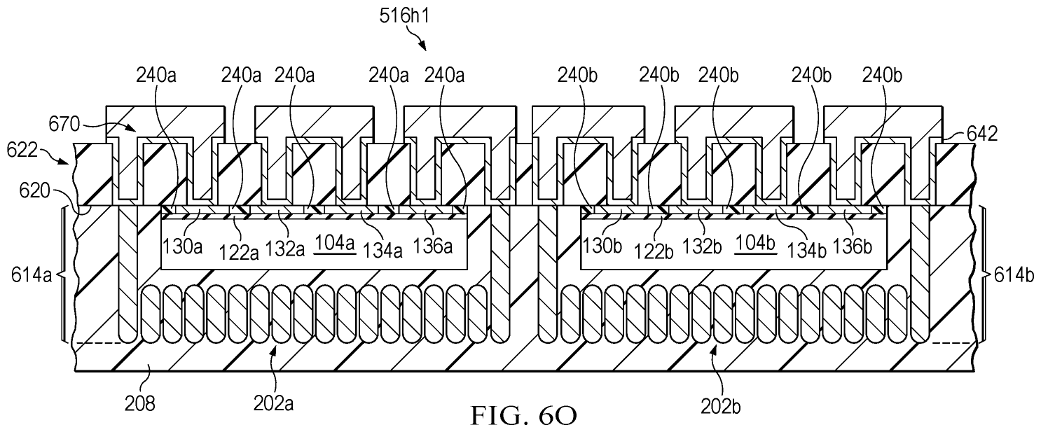

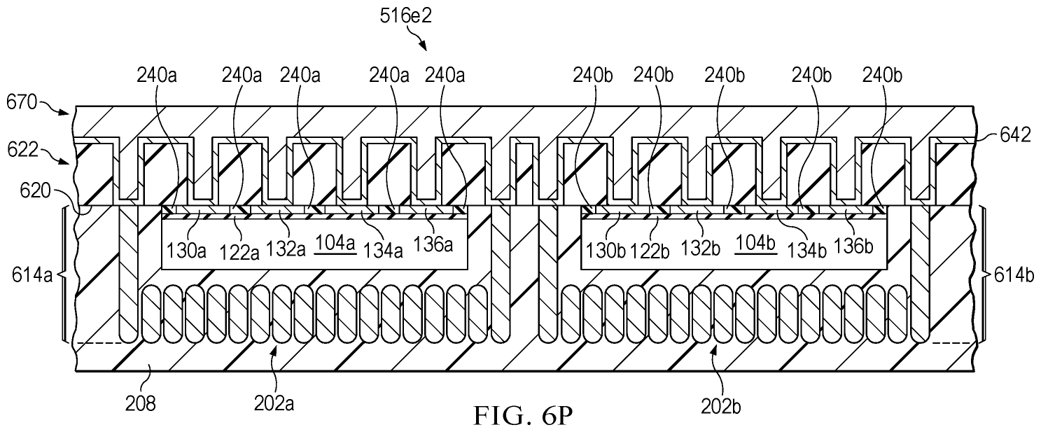

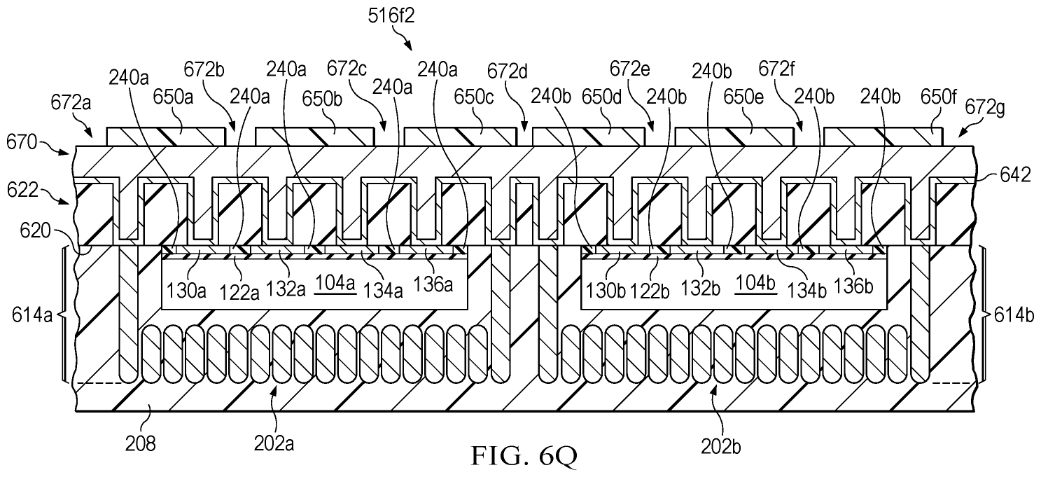

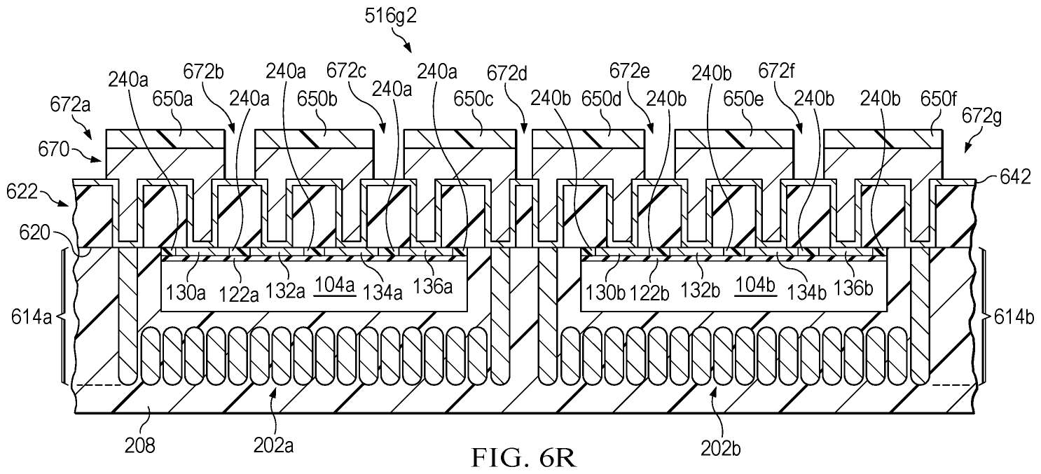

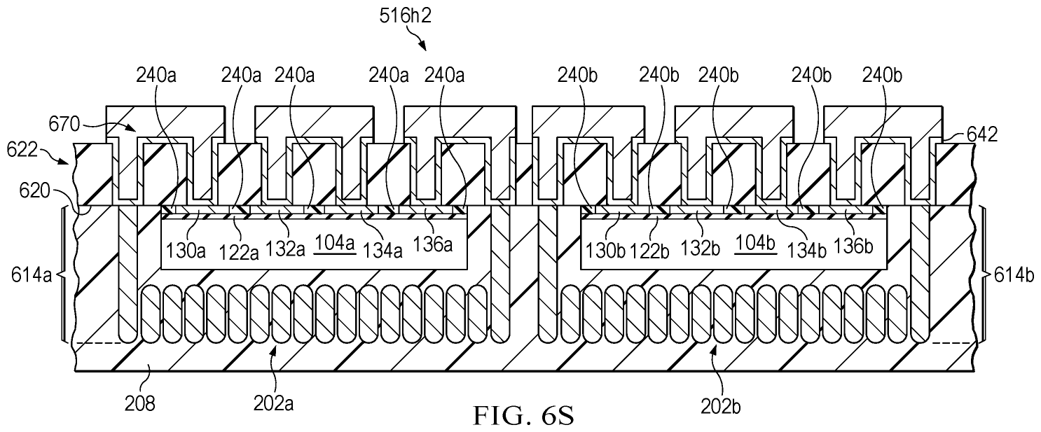

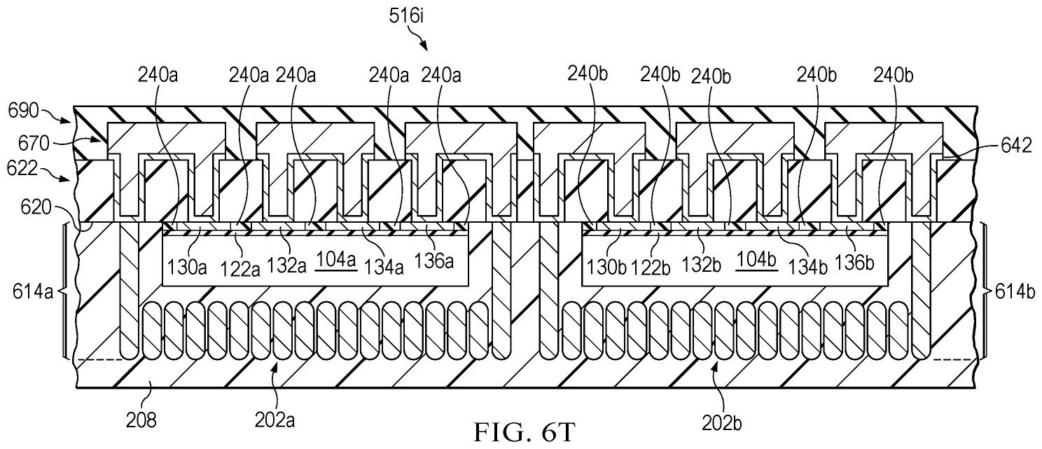

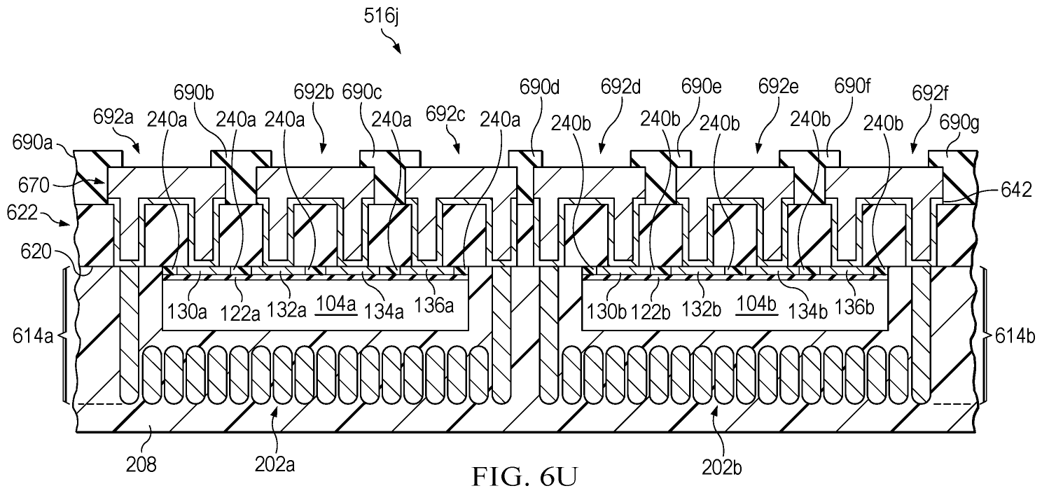

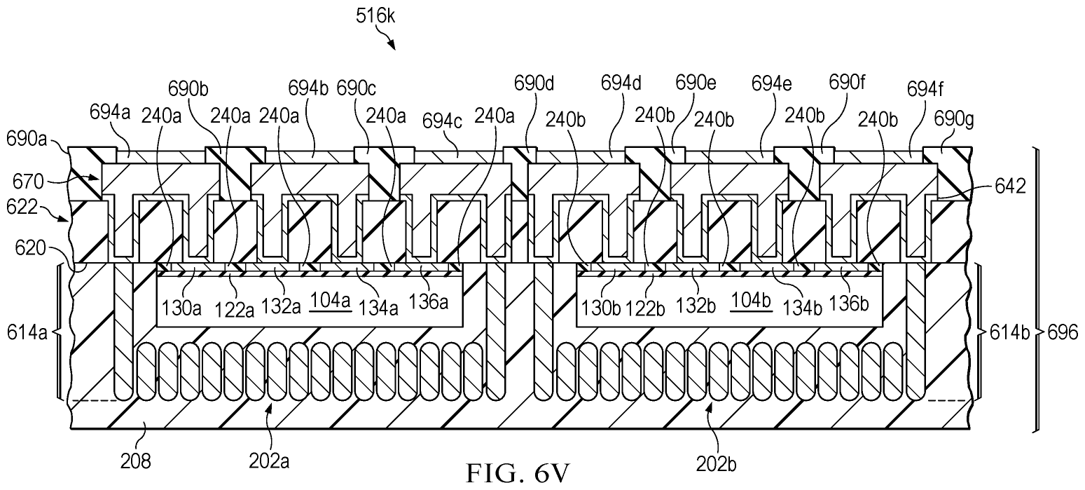

FIG. 5 and FIGS. 6A through 6V illustrate examples of a method of fabricating an integrated circuit with an inductor in a magnetic package, such as integrated circuit 200 of FIGS. 2 through 4C. FIG. 5 illustrates a flowchart 500 of an example method of fabricating the integrated circuit, and FIGS. 6A through 6V are schematic diagrams illustrating various operations of the example method of FIG. 5.

Referring to FIG. 5 and FIG. 6A, in operation 502, a first insulation layer, such as insulation layer 602, can be formed on a wafer 604. Wafer 604 can be coated with passivation layer 122 and can include a via 606 that penetrates through passivation layer 122 to provide an electrical connection to devices in wafer 604. Insulation layer 602 can include a dielectric material with a high break down voltage, such as a polymer material (e.g., PI and PBO), or an oxide material (e.g., Silicon Dioxide). Insulation layer 602 can be coated on wafer 604, or can be formed on wafer 604 by a chemical process (e.g., oxidation).

In operation 504, insulation layer 602 can be patterned. For example, referring to FIG. 6B, insulation layer 602 can be patterned to create an opening 608 to expose via 606. The patterning can be performed based on, for example, photolithography followed by an etching process and a plasma cleaning process.

In operation 506, metal interconnects, such as a metal interconnect 610, can be formed in the patterned insulation layer 602. For example, referring to FIG. 6C, metal interconnect 610, such as an UBM interconnect or a Copper pillar, can be formed in opening 608. In a case where the first metal interconnects (e.g., metal interconnect 610) includes an UBM, they can be formed by a plating operation. After the UBM is formed, a solder ball 611 can be formed on the UBM by a reflow process. In some examples, operations 502, 504, and 506 can be part of a wafer-level chip scale package (CSP) operation.

In operation 508, wafer 604 can be diced to form a semiconductor die, such as semiconductor die 104. The diced wafer 604 also includes metal interconnect 610 and patterned insulation layer 602. Referring to FIG. 6D, insulation layer 602 can be represented by insulation layer 240, and metal interconnect 610 and via 606 can be represented by one of metal interconnects 130 through 136.

In operation 510, semiconductor die 104 can be mounted to a substrate, which can be a carrier substrate, or a package substrate in which metal interconnects are to be formed in subsequent operations. Referring to FIG. 6E, multiple semiconductor dies 104 can be mounted to a carrier substrate 612 via first metal interconnects 130 through 136 and insulation layer 240. For example, semiconductor die 104a can be mounted to carrier substrate 612 via metal interconnects 130a through 136a and insulation layer 240a, and semiconductor die 104b can be mounted to carrier substrate 612 via metal interconnects 130b through 136b and insulation layer 240b. In some examples, semiconductor dies 104a and 104b can be mounted to carrier substrate 612 using a flip-chip bonder, which can be pre-programmed to transfer the dies to particular locations on carrier substrate 612. Carrier substrate 612 can be made of various rigid materials, such as a metal (e.g., iron), glass, or silicon. In some examples, carrier substrate 612 can include a layer of adhesive carrier tape on the surface, and the flip-chip bonder can apply a pressing force to adhere the semiconductor dies onto the carrier tape.

Referring again to FIG. 5, in operation 512, inductor 202 can be mounted to the substrate. Referring to FIG. 6F, multiple inductors 202 can be mounted to carrier substrate 612 and over respective semiconductor dies 104. For example, the stilt portions of inductor 202a can be mounted to carrier substrate 612 (e.g., via a carrier tape) so that the coil portion is over semiconductor die 104a to form a device stack 614a, and the stilt portions of inductor 202b can be mounted to carrier substrate 612 so that the coil portion is over semiconductor die 104b to form a device stack 614b. In some examples, inductors 202a and 202b can be mounted to carrier substrate 612 using a surface mounter, which can be pre-programmed to transfer the inductors to particular locations on carrier substrate 612 and to align with the respective semiconductor dies. Accordingly, carrier substrate 612 can maintain the relative positions of inductors 202a and 202b and semiconductor dies 104a and 104b within the respective device stacks 614a and 614b, and the relative positions of device stacks 614a and 614b.

Referring again to FIG. 5, in operation 514, a magnetic material, such as MMC, can be deposited on semiconductor die 104 and inductor 202 to form encapsulation package 208. The MMC can include metallic particles (e.g., iron particles) and an insulation material (e.g., a polymer resin) in which the metallic particles are suspended. Referring to FIG. 6G, encapsulation package 208 can be formed by depositing an MMC over device stack 614a, and over device stack 614b, to encapsulate both device stacks. The MMC can then be molded to form encapsulation package 208. In some examples, the molding can be performed in a compression molding machine, where the MMC and carrier substrate 612 having the device stacks can be placed in a hot mold. The mold can then be closed by a pressing machine (e.g., a hydraulic press). The pressure exerted by the pressing machine on the mold can squeeze the MMC into empty spaces between the inductors and the semiconductor dies in each device stack (except the spaces filled by insulation layer 240), and mold the MMC into encapsulation package 208. After the MMC is cured and hardened, the mold can be opened to release encapsulation package 208 and carrier substrate 612.

Referring again to FIG. 5, in operation 516, second metal interconnects, such as metal interconnects 260 through 268 of FIGS. 2A and 2B, can be formed external to encapsulation package 208, in which the second metal interconnects are coupled to inductor 202 and metal interconnects 130 through 136.

FIGS. 6H through 6V illustrate example of sub-operations of operation 516 to form the second metal interconnects. Referring to FIG. 6H, in a case where the substrate of operation 512 is carrier substrate 612, in sub-operation 516a of operation 516, carrier substrate 612 can be separated from encapsulation package 208 and device stacks 614a and 614b, and a partial package stack 618 including encapsulation package 208 and device stacks 614a and 614b can be formed. As described above, encapsulation package 208 can be hardened from the curing of the MMC in operation 514, and can maintain the relative positions of inductors 202 and semiconductor dies 104. Accordingly, carrier substrate 612 can be separated from encapsulation package 208 and the device stacks. The separation of carrier substrate 612 can be performed by, for example, heating the carrier tape or irradiating the carrier tape with ultraviolet light, followed by removal of the carrier tape. After carrier substrate 612 is separated from encapsulation package 208 and device stacks 614a and 614b, a surface 620 of partial package stack 618 including the stilt portions of inductors 202, metal interconnects 130 through 136, and insulation layer 240, can be exposed.

Referring to FIG. 6I, in sub-operation 516b, encapsulation package 208 and device stacks 614a and 614b can be flipped, and a second insulation layer, such as insulation layer 622, can be formed on surface 620. Insulation layer 622 can be in contact with the stilt portions of inductors 202, metal interconnects 130 through 136 of semiconductor dies 104, and insulation layers 240 that insulate the metal interconnects. Insulation layer 622 can include, for example, a polymer, an ABF, or a ceramic material. In some examples, insulation layer 622 can be formed on surface 620 by a lamination process using, for example, a vacuum laminator.

Referring to FIG. 6J, in sub-operation 516c, insulation layer 622 can be patterned. As a result of the patterning, openings 630, 632, 634, 636, 638, and 640 can be created to expose the stilt portions of inductors 202 and metal interconnects 130 through 136 of semiconductor dies 104. For examples, openings 630a through 640a can be created over device stack 614a, and openings 630b through 640b can be created over device stack 614b. The patterning can be performed based on, for example, photolithography followed by etching and plasma cleaning. The patterned insulation layer 622 can become electrical insulation layer 269 of package substrate 206 in FIG. 2A and FIG. 2B.

Referring to FIG. 6K, in sub-operation 516d, a metal layer 642 can be formed on the patterned insulation layer 622. The metal seed layer can cover the surfaces of the patterned insulation layer 622, the stilt portions of inductors 202, and metal interconnects 130 through 136 of semiconductor dies 104, and can become metal pads 220 through 230 of FIG. 2A and FIG. 2B. In some examples, metal layer 642 can be a metal seed layer, such as a Titanium seed layer, to provide a starting material for forming the metal interconnects in package substrate 206 in subsequent processing operations. Metal layer 642 can be formed on the patterned insulation layer 622 using various processes, such as an electroplating process, or a spluttering process.

Following sub-operation 516d, additional processing operations can be performed to form the second metal interconnects in package substrate 206. Examples of the processing operations can include a semi-additive process and a subtractive process. A semi-additive process can provide finer line and space patterning of the metal interconnects than a subtractive process. FIGS. 6L through 6O illustrate sub-operations 516e1 through 516h1 of a semi-additive process, and FIGS. 6P through 6S illustrate sub-operations 516e2 through 516h2 of a subtractive process. The sub-operations in FIGS. 6L through 6S can be repeated to fabricate a package substrate having multiple layers of metal interconnects.

Referring to FIG. 6L, in sub-operation 516e1, a photoresist 650 can be formed on metal layer 642. Photoresist 650 can be used to define the locations of the metal interconnects in package substrate 206 in subsequent processing. In some examples, photoresist 650 can include a dry film material that can be hardened by ultraviolet light. In some examples, photoresist 650 can be formed on metal layer 642 by a lamination process using, for example, a vacuum laminator.

Referring to FIG. 6M, in sub-operation 516f1, photoresist 650 can be patterned into photoresist portions 650a through 650g. After the patterning, openings 652a through 652f can be created to expose portions of metal layer 642 and the underlying openings of insulation layer 622. The patterning can be performed based on, for example, photolithography followed by removal of the photoresist by a stripping liquid.

Referring to FIG. 6N, in sub-operation 516g1, a metal layer 670 can be formed in openings 652 (e.g., openings 652a through 652f) and on the exposed portions of metal layer 642. Metal layer 670 can include a Copper layer. Metal layer 670 can include the second metal interconnects in package substrate 206, such as metal interconnects 260 through 268 of FIG. 2A and FIG. 2B. Metal layer 670 can be formed by various processes, such as an electroplating process, and a spluttering process.

Referring to FIG. 6O, in sub-operation 516h1, photoresist portions 650a through 650g and the portions of metal layer 642 under photoresist portions 650a through 650g can be removed. Photoresist portions 650a through 650g can be removed by a stripping liquid. After the photoresist portions are removed, the underlying portions of metal layer 642 that are exposed can be removed by an etching process.

FIGS. 6P through 6S illustrate sub-operations 516e2 through 516h2 of a subtractive process. Referring to FIG. 6P, in sub-operation 516e2, metal layer 670 (e.g., a Copper layer) can be formed on metal layer 642. Metal layer 670 can be formed by various processes, such as an electroplating process, or a spluttering process.

Referring to FIG. 6Q, in sub-operation 516f2, photoresist 650 can be formed on metal layer 670 and patterned into photoresist portions 650a through 650f. After the patterning, openings 672a through 672g can be created to expose portions of metal layer 670. The patterning can be performed based on, for example, photolithography followed by removal of the photoresist by a stripping liquid.

Referring to FIG. 6R, in sub-operation 516g2, the exposed portions of metal layer 670 in openings 672a through 672g can be removed by an etching process, and portions of the metal layer 642 can be exposed. The remaining portions of metal layer 670 can become metal interconnects 260 through 268 of FIG. 2A and FIG. 2B.

Referring to FIG. 6S, in sub-operation 516h2, photoresist portions 650a through 650f and the portions of metal layer 642 exposed by the removal of metal layer 670 can be removed. Photoresist portions 650a through 650f can be removed by a stripping liquid. The exposed portions of metal layer 642 can be removed by an etching process.

FIGS. 6T through 6U illustrate examples of sub-operations 516i through 516k to fabricate other components of the package substrate. Referring to FIG. 6T, in sub-operation 516i, a solder resist layer 690 can be formed on metal layer 670 and portions of insulation layer 622 not covered by metal layer 670. Examples of solder resist material can include an Alkaline developable solder resist, an UV curable solder resist, and a thermally curable solder resist. Solder resist layer 690 can be formed on metal layer 670 and portions of insulation layer 622 by various processes, such as a coating process or a lamination process with a vacuum laminator.

Referring to FIG. 6U, in sub-operation 516j, solder resist layer 690 can be patterned into solder resist portions 690a through 690g. After the patterning, openings 692a through 692f can be created to expose portions of metal layer 670. The patterning solder resist layer 690 can be performed by a screen print process. The patterned solder resist layer 690 can become solder resist layer 270 of FIG. 2A and FIG. 2B.

Referring to FIG. 6V, in sub-operation 516k, metal pads 694a through 694f can be formed on the exposed portions of metal layer 670 in the respective openings 692a through 692f, to form a package stack 696. Metal pads 694a through 694f can represent metal pads 252 through 258 of FIG. 2A and FIG. 2B to improve electrical connections between metal layer 670 (and the metal interconnects) and the solder balls. Metal pads 694a through 694f can include a Silver (Au) or a Palladium (Pd) metal, and can be formed on the exposed portions of metal layer 670 by an electroplating process.

After sub-operation 516k, multiple integrated circuits 200 can be fabricated by dicing package stack 696, so that each integrated circuit 200 can include a device stack of inductor 202 and semiconductor die 104, insulation layer 240 and metal interconnects 130 through 136, all of which can be mounted to package substrate 206 including insulation layer 622, metal layer 670, solder resist layer 690 and metal pads 694. Each integrated circuit 200 can also include an MMC that encapsulates the device stack and insulation layer 240 as encapsulation package 208.

In a case where the substrate of operation 512 is a package substrate, the package substrate can be pre-fabricated from the second insulation layer and can include the second metal interconnects. In such examples, sub-operation 516a can be skipped, and sub-operations 516b through 516k can be performed to form the package substrate, followed by operations 510 through 514 to mount semiconductor die 104 and inductor 202 to the package substrate, and to deposit MMC on semiconductor die 104 and inductor 202 to form encapsulation package 208.

Any of the methods described herein may be totally or partially performed with a computing system including one or more processors, which can be configured to perform the steps. Thus, embodiments can be directed to computing systems configured to perform the steps of any of the methods described herein, potentially with different components performing a respective steps or a respective group of steps. Although presented as numbered steps, steps of methods herein can be performed at a same time or in a different order. Additionally, portions of these steps may be used with portions of other steps from other methods. Also, all or portions of a step may be optional. Additionally, any of the steps of any of the methods can be performed with modules, units, circuits, or other means for performing these steps.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described herein as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

Certain components may be described herein as being of a particular process technology, but these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor.

Uses of the phrase “ground voltage potential” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible, within the scope of the claims.

What is claimed is:

1. An integrated circuit comprising:
a substrate;
a semiconductor die;
metal interconnects coupled between the semiconductor die and the substrate;
an insulation layer coupled between the semiconductor die and the substrate, the insulation layer surrounding the metal interconnects;
an inductor coupled to the substrate; and
a magnetic material encapsulating the semiconductor die, the inductor, the metal interconnects and the insulation layer, the magnetic material having a different material from the insulation layer.

2. The integrated circuit of claim 1, wherein the inductor includes a coil portion and a stilt portion, the stilt portion coupled to the substrate.

3. The integrated circuit of claim 2, wherein the coil portion is on the semiconductor die.

4. The integrated circuit of claim 2, further comprising a capacitor encapsulated in the magnetic material and coupled to the substrate;
wherein the coil portion is on the capacitor.

5. The integrated circuit of claim 1, wherein the magnetic material includes metal particles and an epoxy resin in which the metal particles are suspended.

6. The integrated circuit of claim 1, wherein the insulation layer has a higher breakdown voltage than the magnetic material.

7. The integrated circuit of claim 6, wherein the insulation layer includes a dielectric material.

8. The integrated circuit of claim 7, wherein the dielectric material includes at least one of: a Polyimide material, a Polybenzoxazole material, or an oxide material.

9. The integrated circuit of claim 1, wherein the semiconductor die includes a passivation layer coupled to the metal interconnects.

10. The integrated circuit of claim 1, wherein the metal interconnects include at least one of: pillars, or under bump metallization (UBM) interconnects.

11. The integrated circuit of claim 1, wherein the insulation layer is a first insulation layer, the metal interconnects are first metal interconnects, and the substrate includes:
first metal pads on a first side of the substrate, the first metal pads coupled to the first metal interconnects;
second metal pads on a second side of the substrate opposite to the first side;
a second insulation layer between the first side and the second side; and
second metal interconnects in the second insulation layer and coupled between the first metal pads and the second metal pads.

12. The integrated circuit of claim 11, wherein:
the first metal pads and the second metal interconnects include a Copper metal;
the second metal pads include at least one of a Palladium metal or a Silver metal; and
the second insulation layer includes at least one of: a polymer material, an Ajinomoto Build-up Film, or a ceramic material.

13. The integrated circuit of claim 11, further comprising a solder resist layer on the second side.

14. A method comprising:
forming an insulation layer on a wafer;
patterning the insulation layer;
forming first metal interconnects in the patterned insulation layer;
dicing the wafer to form a semiconductor die, the diced wafer further including the first metal interconnects and the patterned insulation layer;
mounting the semiconductor die to a substrate via the first metal interconnects and the patterned insulation layer;
mounting an inductor to the substrate;
depositing a magnetic material on the semiconductor die and the inductor to form an encapsulation package; and
forming second metal interconnects outside of the encapsulation package, in which the second metal interconnects are coupled to the first metal interconnects and the inductor.

15. The method of claim 14, wherein:
the inductor has a stilt portion and a coil portion;
the stilt portion is coupled to the substrate; and
the coil portion is on the semiconductor die

16. The method of claim 14, wherein the insulation layer includes a dielectric material including at least one of: a Polyimide material, a Polybenzoxazole material, or an oxide material; and
wherein the substrate includes at least one of: a polymer material, an Ajinomoto Build-up Film, or a ceramic material.

17. The method of claim 14, further comprising:
patterning the substrate;
depositing a metal layer on part of the patterned substrate to form the second metal interconnects.

18. The method of claim 17, further comprising:
forming a photoresist layer on the patterned substrate;
patterning the photoresist layer to expose part of the patterned substrate; and
depositing the metal layer on the exposed part of the patterned substrate to form the second metal interconnects.

19. The method of claim 17, wherein the metal layer is a first metal layer, and the second metal interconnects are formed by:
forming a photoresist layer on the metal layer;
patterning the photoresist layer; and
etching portions of the metal layer exposed in the patterned photoresist layer to form the second metal interconnects.

20. The method of claim 17, wherein the insulation layer is a first insulation layer, and the method further comprises:
forming a second insulation layer on the second metal interconnects and the patterned substrate;
patterning the second insulation layer to expose portions of the second metal interconnects; and
forming metal pads on the exposed portions of the second metal interconnects.

21. The method of claim 14, wherein:
the substrate is a first substrate;
the magnetic material is deposited on the semiconductor die, the inductor, and the first substrate; and
the method further comprises:
separating the first substrate from the magnetic material, the semiconductor die, and the inductor;
mounting the magnetic material, the semiconductor die, and the inductor to a second substrate; and
forming the second metal interconnects in the second substrate.
